(19) United States
(12) Patent Application Publication
(10) Pub. No.: US 2006/0255471 A1
(43) Pub. Date: Nov. 16, 2006

(54) Flip chip package having protective cap and method of fabricating the same

(76) Inventors: Yong-Kwan Lee, Cheonan-city (KR); Tae-Duk Nam, Asan-city (KR)

Correspondence Address: HARNESS, DICKEY & PIERCE, P.L.C., P.O. BOX 8910, RESTON, VA, 20195, US

(21) Appl. No.: 11/404,756

(22) Filed: Apr. 17, 2006

Related U.S. Application Data
(62) Division of application No. 10/766,210, filed on Jan. 29, 2004.

(30) Foreign Application Priority Data
Jan. 29, 2003 (KR) 2003-5936

(51) Int. Cl. H01L 23/48

(52) U.S. Cl. 257/778

(57) ABSTRACT

The flip chip package includes a semiconductor chip electrically connected to a circuit substrate. A protective cap is disposed over the semiconductor chip, and includes at least one portion extending beyond an edge of the semiconductor chip.

### CROSS-REFERENCE TO RELATED APPLICATIONS

This is a divisional of, and claims priority under 35 U.S.C. § 120 to, U.S. application Ser. No. 10/766,210, filed Jan. 29, 2004. This application claims the priority of Korean Patent Application No. 2003-5936 filed on Jan. 29, 2003, in the Korean Intellectual Property Office, the disclosure of which is hereby incorporated by reference in its entirety.

### BACKGROUND OF THE INVENTION

1. Field of the Invention

The present invention relates to a semiconductor package and a method of fabricating the same, and particularly, to a flip chip package.

2. Description of the Related Art

High-speed, high-performance, and high-density semiconductor device packaging is required for flat and miniature electronic devices. In this respect, flip chip packaging offers an effective technology for reducing the size of a chip package.

A flip chip package has excellent electrical and heat conductive properties because a connecting distance between a semiconductor chip and a pad on a circuit substrate is short. However, damage such as chip cracks may be caused by shocks when manipulating the flip chip because a back side that opposes an active side in the semiconductor chip is not protected. Such damage degrades product reliability and reduces productivity.

To solve the above problems, U.S. Pat. No. 5,936,304 teaches a structure in which a passivation layer is formed on the back side of a semiconductor chip. However, forming the passivation layer on the backside of the semiconductor chip requires an additional processing step, and equipment therefor that increases fabrication costs and reduces yield.

### SUMMARY OF THE INVENTION

The flip chip package according to one exemplary embodiment of the present invention includes a semiconductor chip electrically connected to a circuit substrate. A protective cap is disposed over the semiconductor chip, and includes at least one portion extending beyond an edge of the semiconductor chip.

In one exemplary embodiment, a molding resin seals the electrical connection between the semiconductor chip and the circuit substrate. In another exemplary embodiment, the molding resin at least assists in mounting the protective cap over the semiconductor substrate. For example, the molding resin engages the extended portion of the protective cap.

In fabricating the flip chip package, the protective cap attached to a release tape is clamped over a back side of the semiconductor chip using a mold. The molding resin is then formed using the mold. In one exemplary embodiment, the release tape adheres to an upper portion of the mold during the formation of the molding resin such that removal of the mold causes simultaneous removal of the release tape.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a flip chip package according to a first embodiment of the present invention;

FIGS. 2A through 2D are orderly cross-sectional views of processes for explaining a method of fabricating a flip chip package according to the first embodiment of the present invention;

FIG. 3 is a cross-sectional view of a flip chip package according to a second embodiment of the present invention; and

FIGS. 4A through 4D are orderly cross-sectional views of processes for explaining a method for fabricating a flip chip package according to the second embodiment of the present invention.

FIG. 5 illustrates a cross-sectional view of a flip chip package with a dovetail groove having a thickness less than a thickness of a protective cap according to another example embodiment of the present invention.

### DETAILED DESCRIPTION OF THE INVENTION

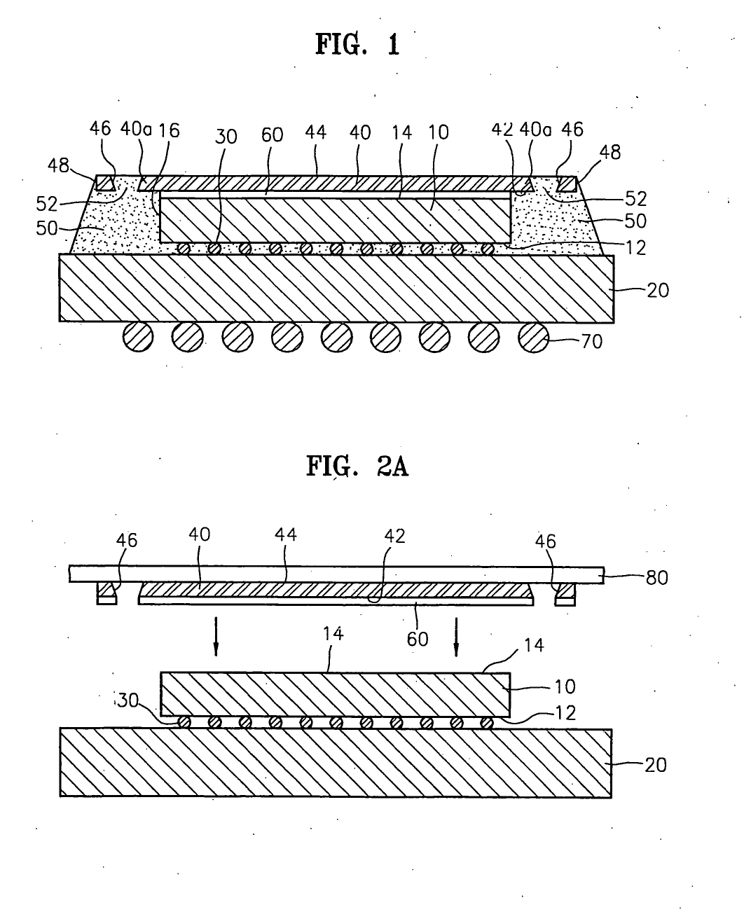

FIG. 1 is a cross-sectional view of the structure of a flip chip package according to a first embodiment of the present invention. The flip chip package according to the first embodiment of the present invention includes a semiconductor chip 10 and a circuit substrate 20. The semiconductor chip 10 has an active side 12 on which a plurality of bonding pads (not shown) are formed and a back side 14 opposing the active side 12. The circuit substrate 20 has a plurality of electrode pads (not shown) formed to correspond to the bonding pads on the semiconductor chip 10. The semiconductor chip 10 includes a memory circuit such as a dynamic random access memory (DRAM) or a static random access memory (SRAM). The circuit substrate 20 is electrically connected to the active side of the semiconductor chip 10 via a plurality of solder bumps 30. Also, a plurality of solder balls 70, required to connect the semiconductor chip 10 to an external device, are formed on a lower surface of the circuit substrate 20.

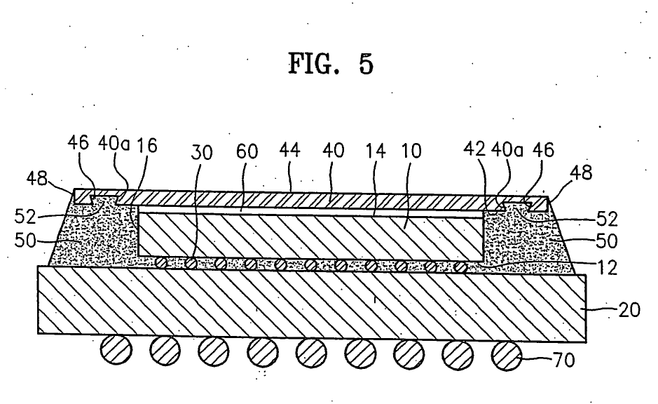

A protective cap 40 is attached to the back side 14 of the semiconductor chip 10. The protective cap 40 includes a first surface 42 facing the semiconductor chip 10 and a second surface 44 opposite of the first surface 42 and exposed to the outside of the flip package. Also, the protective cap 40 includes an extended portion 40a extending beyond the periphery of the semiconductor chip 10. A dovetail groove 46, opening toward the first surface 42, is formed in the extended portion 40a. In FIG. 1, the dovetail groove 46 is represented as an opening having a depth equal to the entire thickness of the protective cap 40, but it may be formed as a blind hole having a depth less than the thickness of the protective cap 40 as illustrated in FIG. 5. The protective cap 40 includes metal to protect the semiconductor chip 10 from shocks. For example, the protective cap 40 may be made of copper (Cu), copper alloy, aluminum (Al), or aluminum alloy. The protective cap 40 is capable of maintaining the excellent heat-conductive property of the flip chip package.

A molding resin layer 50 made of epoxy molding compound (EMC), for example, is formed to seal the electrical connection between the semiconductor chip 10 and the circuit substrate 20. The molding resin layer 50 is formed to cover the side surface 16 of the semiconductor chip 10 and the side surface 48 of the protective cap 40. The molding resin layer 50 includes a dovetail portion 52, which is received in the dovetail groove 46 formed in the extended portion 40a of the protective cap 40. The protective cap 40 may be attached to the semiconductor chip 10 with an improved adhesive force due to the engagement of the dovetail groove 46 of the protective cap 40 and the dovetail portion 52 of the molding resin layer 50.

An adhesion layer 60 is disposed between the back side 14 of the semiconductor chip 10 and the protective cap 40. The back side 14 of the semiconductor chip 10 and the protective cap 40 are attached to each other through a thermo-compression bonding process by interposing the adhesion layer therebetween. In one exemplary embodiment, a material having an excellent heat-release property is used as the material of the adhesion layer. For example, the adhesion layer 60 may be made of bismaleimide resin-based adhesive. However, the adhesion layer 60 may also be omitted.

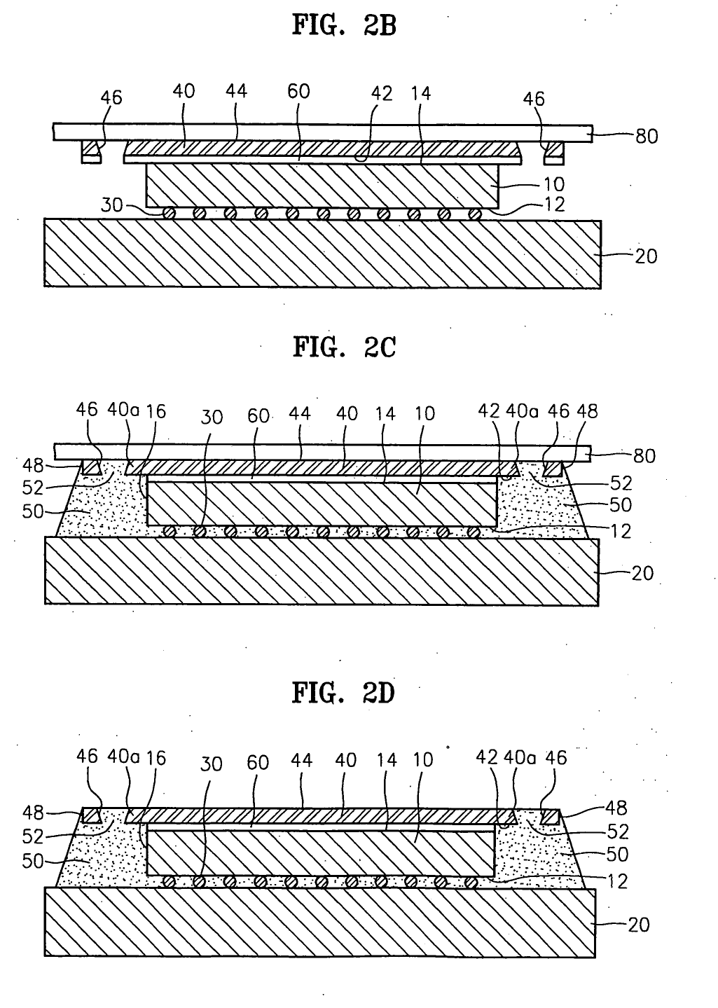

FIGS. 2A through 2D are orderly cross-sectional views of processes for explaining a method of fabricating the flip chip package according to the first embodiment of the present invention. Reference numerals in FIGS. 2A through 2D denote the same elements as those of FIG. 1.

Referring to FIG. 2A, the semiconductor chip 10 is electrically connected to a predetermined portion of the circuit substrate 20 via a plurality of solder bumps 30. Thereafter, the protective cap 40 with the dovetail groove 46 is attached to a release tape 80. The second surface 44 of the protective cap 40 to be exposed to the outside of the flip chip package in a subsequent process is attached to one surface of the release tape 80, and a tape-shaped adhesion layer 60 is attached to the first surface 42 of the protective cap 40 so that the protective cap 40 may be attached to the back side 14 of the semiconductor chip 10. However, the adhesion layer 60 may also be omitted.

Also, a mold having an upper mold portion and a lower mold portion for fabricating a semiconductor package is prepared. The preparation of a mold is well-known in the art, and accordingly, the detailed description thereof will be omitted. Furthermore, the pattern of the molds will be readily apparent from the following and foregoing description.

Referring to FIG. 2B, the upper mold portion and the lower mold portion of the mold are clamped together with the release tape 80 and the circuit substrate 20 interposed between the two mold patterns such that the back side 14 of the semiconductor chip 10 and the first surface 42 of the protective cap 40 face each other. For the purposes of clarity only, the upper and lower mold portions are not illustrated in FIGS. 2B and later described in FIG. 2C. In case that the adhesion layer 60 is formed on the first surface 42 of the protective cap 40 as shown in FIG. 2B, the back side 14 of the semiconductor chip 10 and the adhesion layer 60 face each other. Here, the clamping of the upper and lower mold portions may be performed such that the circuit substrate 20 is positioned on the lower mold portion of the mold and the release tape 80, to which the protective cap 40 is attached, is fixed on the upper mold portion of the mold.

Referring to FIG. 2C, molding resin is injected into the clamped mold to form the molding resin layer 50. The molding resin layer 50 seals the electrical connection between the semiconductor chip 10 and the circuit substrate 20, the side surface 16 of the semiconductor chip 10 and the side surface 48 of the protective cap 40. At the same time, the protective cap 40 is attached to the back side 14 of the semiconductor chip 10 through a thermo-compression bonding process using the mold. Here, the clamping pressure in the molding process is from about several tens of tons to one hundred tons, and the molding is performed at the temperature of 155° C. ˜190° C., more preferably, at about 180° C. During this process, the release tape 80, which may be made of a foaming resin, adheres to the upper mold portion.

The molding resin injected into the mold flows into the dovetail groove 46 formed in the extended portion 40a of the protective cap 40 to form the dovetail portion 52, which is received in the dovetail groove 46, in the molding resin layer 50.

Referring to FIG. 2D, the upper mold portion and the lower mold portion of the mold are separated from each other. Consequently, the release tape 80 attached to the upper mold portion of the mold, which is maintained to be at relatively high temperature separates from the protective cap 40 at the same time when the upper and lower mold portions are separated from each other.

Then, the molding resin layer 50 and the adhesion layer 60 are cured by a heating process during which the protective cap 40 is attached to the back side 14 of the semiconductor chip 10. For example, the resultant structure of FIG. 2D is heat-treated for a few hours in an oven at a temperature of about 170° C.

Then a plurality of solder balls 70 are formed on the lower surface of the circuit substrate 20 to connect the semiconductor chip 10 with an external device, thus completing the structure shown in FIG. 1.

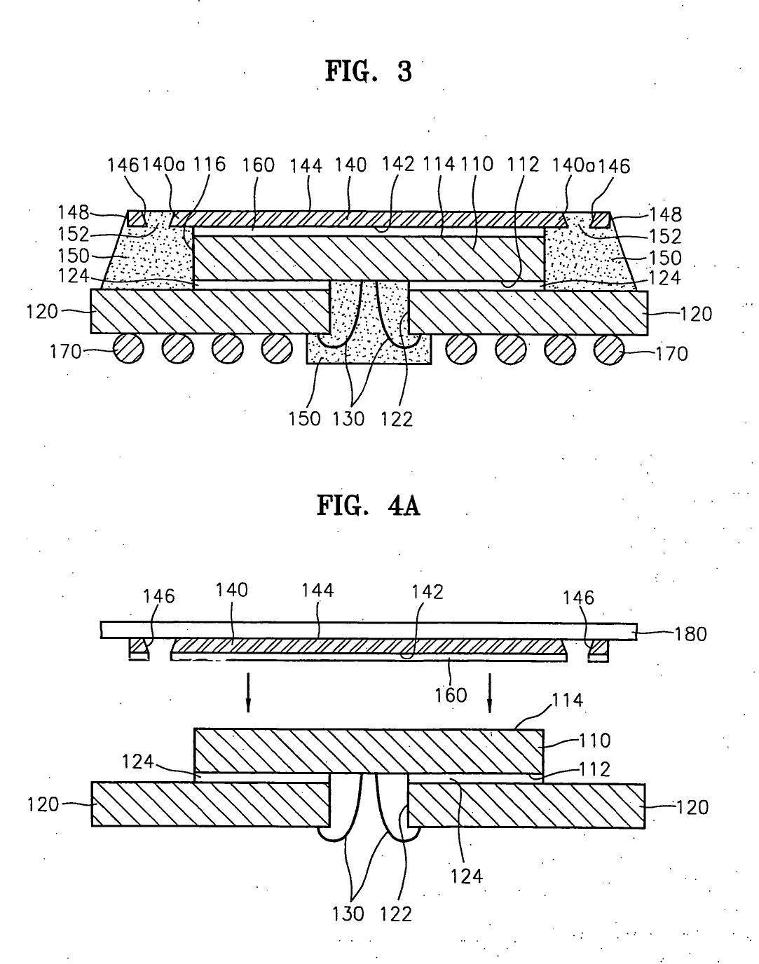

FIG. 3 is a cross-section of the structure of a flip chip package according to a second embodiment of the present invention. Referring to FIG. 3, the flip chip package according to the second embodiment of the present invention includes a semiconductor chip 110 and a circuit substrate 120. The semiconductor chip 110 has an active side 112 and a back side 114 opposing the active side 112. The circuit substrate 120, as described in more detail below, is electrically connected to the semiconductor chip 110. The semiconductor chip 110 is attached to an upper surface of the circuit substrate 120 via a first adhesion layer 124.

A hole 122 penetrating the circuit substrate 120 is formed in the circuit substrate 120, and the semiconductor chip 110 covers one end of the hole 122. The active side 112 of the semiconductor chip 110 is electrically connected to the lower surface of the circuit substrate 120 via a plurality of wires 130 passing through the hole 122. Also a plurality of solder balls 170 for connecting the semiconductor chip 110 to an external device are formed on the lower surface of the circuit substrate 120.

A protective cap 140 is attached to the back side 114 of the semiconductor chip 110. The protective cap 140 includes a first surface 142 facing the semiconductor chip 110 and a second surface 144, opposite the first surface 142 and exposed to the outside of the flip chip package. Also, the protective cap 140 includes an extended portion 140a extending beyond the periphery of the semiconductor chip 110. A dovetail groove 146 opening toward the first surface 142 is formed in the extended portion 140a. As in the description of the dovetail groove 46 in FIG. 1, the dovetail groove 146 shown in FIG. 3 may be formed as an opening having a depth equal to the entire thickness of the protective cap 140, or may be formed as a blind hole having a predetermined depth less than the thickness of the protective cap 140. The protective cap 140 includes a metal to protect the semiconductor chip 110 from shocks. For example, the protective cap 140 may be made of copper (Cu), copper alloy, aluminum (Al), or aluminum alloy. The protective cap is capable of maintaining the excellent heat conductive property of the flip chip package.

A molding resin layer 150 made of EMC, for example, is formed to seal the electrical connection between the semiconductor chip 110 and the circuit substrate 120. The molding resin layer 150 is formed to cover the side surface 116 of the semiconductor chip 110, the side surface 148 of the protective cap 140, and the connecting portion corresponding to the wires 130. The molding resin layer 150 includes a dovetail portion 152 received in the dovetail groove 146 formed in the extended portion 140a of the protective cap 140. The protective cap 140 may be attached to the semiconductor chip 110 with an improved adhesive force through the engagement of the dovetail groove 146 of the protective cap 140 and the dovetail portion 152 of the molding resin layer 150.

A second adhesion layer 160 is disposed between the back side 114 of the semiconductor chip 110 and the protective cap 140. The back side 114 of the semiconductor chip 110 and the protective cap 140 are attached to each other through a thermo-compression bonding process with the second adhesion layer 160 interposed therebetween. The material forming the second adhesion layer 160 is same as that of the adhesion layer 60 shown in FIG. 1. However, the second adhesion layer 160 may be omitted.

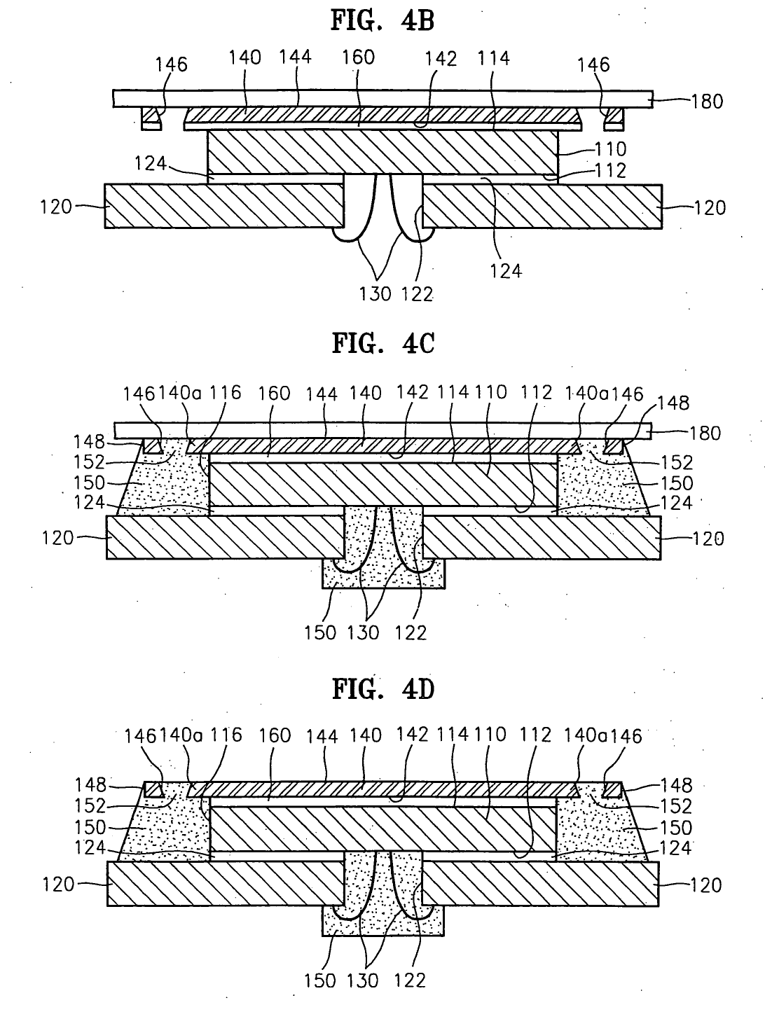

FIGS. 4A through 4D are orderly cross-sectional views of processes for explaining a method for fabricating the flip chip package according to the second embodiment of the present invention. Reference numerals in FIG. 4A through 4D denote the same elements as those in FIG. 3.

Referring to FIG. 4A, in order to electrically connect the semiconductor chip 110 to the circuit substrate 120, the semiconductor chip 110 is attached to an upper surface of the circuit substrate 120 via the first adhesion layer 124. Then, the active side 112 of the semiconductor chip 110 and the lower surface of the circuit substrate 120 are electrically connected to each other via a plurality of wires 130 passing through the hole 122 formed in the circuit substrate 120.

Thereafter, the protective cap 140 with the dovetail groove 146 is attached to a release tape 80. The release tape 180 is made of a foaming resin film. The second surface 144 of the protective cap 140 is attached to one surface of the release tape 180, and a tape-shaped second adhesion layer 160 is attached to the first surface 142 of the protective cap 140. However, the second adhesion layer 160 may be omitted.

Also, a mold including an upper mold portion and a lower mold portion for fabricating a semiconductor package is prepared. As discussed above, the preparation of a mold is well-known in the art, and will not be described for the sake of brevity. The pattern of the upper and lower mold portions will be readily apparently from the following and foregoing detailed description. Furthermore, for the purpose of clarity only, the upper and lower mold portions will not be shown in FIGS. 4B-4C.

Referring to FIG. 4B, the upper mold portion and the lower mold portion of the mold are clamped together with the release tape 180 and the circuit substrate 120 interposed therebetween in a manner that the back side 114 of the semiconductor chip 110 and the first surface 142 of the protective cap 140 face each other. Here, in case that the second adhesion layer 160 is formed on the first surface 142 of the protective cap 140 as shown in FIG. 4B, the back side 114 of the semiconductor chip 110 and the second adhesion layer 160 face each other. The clamping of the upper and lower mold portions may be performed such that the circuit substrate 120 is positioned on the lower mold portion of the mold and the release tape 180, to which the protective cap 140 is attached, is fixed on the upper mold portion of the mold.

Referring to FIG. 4C, molding resin is injected into the clamped mold to form the molding resin layer 150. The molding resin layer 150 seals the electrical connection between the semiconductor chip 110 and the circuit substrate 120 including the wires 130, the side surface 116 of the semiconductor chip 110 and the side surface 148 of the protective cap 140. At the same time, the protective cap 140 is attached to the back side 114 of the semiconductor chip 110 through a thermo-compression bonding process using the mold. Here, the clamping pressure and temperature in the molding process are the same as those described with reference to FIG. 2C. During this process, the release tape 180 adheres to the upper mold portion.

When the molding resin is injected into the mold, the injected molding resin flows into the dovetail groove 146 formed in the extended portion 140a of the protective cap 140 to form the dovetail portion 152.

Referring to FIG. 4D, the upper mold portion and the lower mold portion of the mold are separated from each other. Consequently, the release tape 180 attached to the upper mold portion of the mold, which is maintained at a relatively high temperature, separates from the protective cap 140 when the upper and lower mold portions are separated from each other.

Thereafter, the molding resin layer 150 and the second adhesion layer 160 are cured by heating treatment during which the protective cap 140 is attached to the back side 114 of the semiconductor chip 110 in the same manner as that described referring to FIG. 2D.

Thereafter, a plurality of solder balls 170 are formed on the lower surface of the circuit substrate 120 for connecting the semiconductor chip 110 and an external element, thus completing the structure shown in FIG. 3.

In the flip chip package according to the present invention, the protective cap is attached to the back side of the semiconductor chip, which is electrically connected to the circuit substrate. Therefore, the protective cap protects the semiconductor chip from shocks and prevents damage such as chip cracks, and the excellent heat conductive property of the chip package may be maintained by forming the protective cap out of metal. Also, since the dovetail groove is formed on the extended portion of the protective cap, the molding resin flowing into the dovetail groove forms the dovetail portion engaged with the dovetail groove, and thus, the protective cap may be attached to the back side of the semiconductor chip with improved adhesive force.

In the method for fabricating the flip chip package according to the present invention, the protective cap is attached to the back side of the semiconductor chip when the mold for forming the resin is attached. Also, the release tape used to attach the protective cap is made of a foaming resin film, and released and removed from the protective cap as soon as the upper mold portion and the lower mold portion of the mold are separated from each other.

Therefore, the protective cap attached to the back side of the semiconductor chip according to the present invention is capable of effectively protecting the back side of the semiconductor chip from being damaged while maintaining the excellent heat conductive property of the package. Also, since the flip chip package can be fabricated by attaching the protective cap to the back side of the semiconductor chip without increasing the number of fabrication processes, product reliability and yield increase.

While the present invention has been particularly shown and described with reference to exemplary embodiments thereof, it will be understood by those of ordinary skill in the art that various changes in form and details may be made therein without departing from the spirit and scope of the present invention.

1.-16. (canceled)

17. A method for fabricating a flip chip package, comprising:
electrically connecting a first side of a semiconductor chip to a circuit substrate;
clamping a protective cap attached to release tape over a second side of the semiconductor chip using a mold, the second side of the semiconductor chip opposing the first side;
forming a molding resin layer that seals the electrical connection between the semiconductor chip and the circuit substrate using the mold; and
removing the mold and release tape.

18. The method of claim 17, wherein the protective cap includes metal.

19. The method of claim 18, wherein the protective cap is made of one selected from the group consisting of copper (Cu), copper alloy, aluminum (Al), and aluminum alloy.

20. The method of claim 17, wherein the semiconductor chip and the circuit substrate are electrically connected to each other via a plurality of solder bumps.

21. The method of claim 17, wherein the semiconductor chip and the circuit substrate are electrically connected to each other via a plurality of bonding wires.

22. The method of claim 17, further comprising:
attaching an adhesion layer to the protective cap.

23. The method of claim 22, wherein the clamping step is performed such that the adhesion layer is disposed between the second side and the protective cap.

24. The method of claim 17, wherein
the forming step causes the release tape to adhere to the mold; and
the removing the mold step causes removal of the release tape simultaneously with the removal of the mold.

25. The method of claim 24, wherein
the forming step includes a heat treatment step; and
the release tape is made of a foaming resin film.

26. The method of claim 17, wherein the release tape is made of a foaming resin film.

27. The method of claim 17, wherein the protective cap includes at least one portion extending beyond an edge of the semiconductor chip.

28. The method of claim 27, wherein the forming step forms the molding resin such that the molding resin engages the extended portion of the protective cap.

29. The flip chip package of claim 28, wherein
the protective cap includes a dovetail groove in the extended portion; and
the forming step forms the molding resin layer in the dovetail groove.

30. The flip chip package of claim 17, wherein the forming step forms the molding resin layer such that the molding resin layer at least assists in mounting the protective cap over the second side of the semiconductor chip.
